(19) United States
(12) Patent Application Publication
(10) Pub. No.: US 2024/0063222 A1
(43) Pub. Date: Feb. 22, 2024

(54) SEMICONDUCTOR STRUCTURE

(71) Applicant: CHANGXIN MEMORY TECHNOLOGIES, INC., Hefei (CN)

(72) Inventor: Miaomiao CHEN, Hefei (CN)

(21) Appl. No.: 18/154,796

(22) Filed: Jan. 14, 2023

(30) Foreign Application Priority Data
Aug. 17, 2022 (CN) 202210989438.1

(51) Int. Cl. H01L 27/10

(52) U.S. Cl. CPC H01L 27/101; H10B 10/18

(57) ABSTRACT

Embodiments relate to a semiconductor structure, including: an active layer including a channel region; a first dielectric layer covering a top surface of the channel region; a gate layer covering a top surface of the first dielectric layer, where the active layer, the first dielectric layer and the gate layer constitute a first capacitor, and the first capacitor is coupled between a first potential and a second potential; two groups of first conductive layers, where the first conductive layers among the two groups of first conductive layers are electrically connected to each other; two groups of second conductive layers, where each of the second conductive layers clads a side surface and a bottom surface of the first conductive layer, one group of the second conductive layers is electrically connected to a third potential, and the other group of the second conductive layers is electrically connected to a fourth potential.

### CROSS-REFERENCE TO RELATED APPLICATION

This application claims priority to Chinese Patent Application No. 202210989438.1, titled “SEMICONDUCTOR STRUCTURE” and filed to the State Patent Intellectual Property Office on Aug. 17, 2022, the entire contents of which are incorporated herein by reference.

### TECHNICAL FIELD

Embodiments of the present disclosure relate to the field of semiconductor technology, and more particularly, to a semiconductor structure.

### BACKGROUND

As a geometric dimension of a process for an integrated circuit is decreased, more and more transistors are integrated on one chip, such that density and speed of a chip of the integrated circuit are significantly improved. However, when the speed of the integrated circuit is excessively high, an excessively high transient current may be generated when the transistor is turned on or off, thereby causing a change in a supply voltage. Consequently, the integrated circuit is susceptible to noise of a power supply. To resolve this problem, a decoupling capacitor is designed in a semiconductor structure to reduce the noise of the power supply, to provide a stable power supply.

However, as an integration degree of the integrated circuit increases, a higher requirement on a capacitance value of the decoupling capacitor is put forward, and the capacitance value of the decoupling capacitor needs to be increased to provide the stable power supply.

### SUMMARY

Embodiments of the present disclosure provide a semiconductor structure.

The embodiments of the present disclosure provide a semiconductor structure, including: an active layer, where the active layer includes a channel region; a first dielectric layer, where the first dielectric layer covers a top surface of the channel region; a gate layer covering a top surface of the first dielectric layer, where the active layer, the first dielectric layer and the gate layer constitute a first capacitor, and a first capacitor is coupled between a first potential and a second potential; at least two groups of first conductive layers positioned on a side of the gate layer away from the active layer, where the first conductive layers among the at least two groups of first conductive layers are electrically connected to each other; two groups of second conductive layers cladding a side surface and a bottom surface of the first conductive layer, where one group of the second conductive layers is electrically connected to a third potential, and the other group of the second conductive layers is electrically connected to a fourth potential; and two groups of second dielectric layers positioned between the first conductive layers and the second conductive layers, where the second dielectric layers are configured to isolate the first conductive layers from the second conductive layers. The two groups of the first conductive layers, the two groups of the second conductive layers and the two groups of the second dielectric layers together constitute a second capacitor, and the first capacitor and the second capacitor are stacked in a direction perpendicular to a top surface of the gate layer.

### BRIEF DESCRIPTION OF THE DRAWINGS

Exemplary descriptions are made to one or more embodiments with reference to pictures in the corresponding drawings, and these exemplary descriptions do not constitute limitations on the embodiments. Unless otherwise stated, the figures in the accompanying drawings do not constitute a scale limitation. To describe the technical solutions of the embodiments of the present disclosure or those of the prior art more clearly, the accompanying drawings required for describing the embodiments will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a schematic top view of a semiconductor structure according to an embodiment of the present disclosure;

FIG. 2 is an enlarged diagram of a cross-sectional structure of 1 in FIG. 1;

FIG. 3 is a schematic diagram of a three-dimensional structure of a semiconductor structure according to an embodiment of the present disclosure;

FIG. 4 is a circuit diagram corresponding to FIG. 3;

FIG. 5 is another circuit diagram corresponding to FIG. 3;

FIG. 6 is a schematic diagram of a three-dimensional structure of another semiconductor structure according to an embodiment of the present disclosure;

FIG. 7 is a circuit diagram corresponding to FIG. 6;

FIG. 8 is a schematic top view of another semiconductor structure according to an embodiment of the present disclosure;

FIG. 9 is a schematic diagram of a three-dimensional structure of still another semiconductor structure according to an embodiment of the present disclosure; and

FIG. 10 is a circuit diagram corresponding to FIG. 9.

### DETAILED DESCRIPTION

As can be learned from the background art, at present, a capacitance value of a decoupling capacitor needs to be further increased, to provide a stable power supply.

Embodiments of the present disclosure provide a semiconductor structure, in which an active layer, a first dielectric layer, and a gate layer constitute a first capacitor. Two groups of second conductive layers are provided, and one group of the second conductive layers and the other group of the second conductive layers are respectively connected to two potentials, such that the two groups of the second conductive layers may be used as an upper electrode and a lower electrode respectively, to constitute a second capacitor. The second dielectric layer is positioned between the first conductive layer and the second conductive layer, and serves as a dielectric layer of the second capacitor. Because the second capacitor is a capacitor group comprising a plurality of columnar second conductive layers, and the capacitor having a columnar structure is smaller in volume, such that a capacitance value of the second capacitor can be increased, and meanwhile, the second capacitor does not occupy too much volume. In addition, the second capacitor and the first capacitor form a stack structure, which is advantageous to increasing total number of capacitors and the capacitance values thereof, thereby improving stability of the supply voltage.

The embodiments of the present disclosure will be described in detail below in conjunction with the accompanying drawings. However, a person of ordinary skill in the art may understand that in the embodiments of the present disclosure, many technical details are put forward such that a reader can better understand the present disclosure. However, the technical solutions requested to be protected by the present disclosure may also be implemented even without these technical details or various variations and modifications based on the following embodiments.

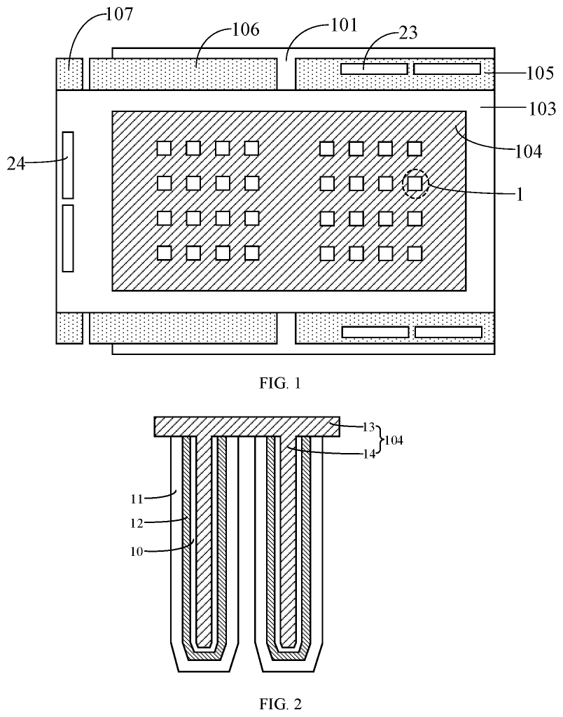

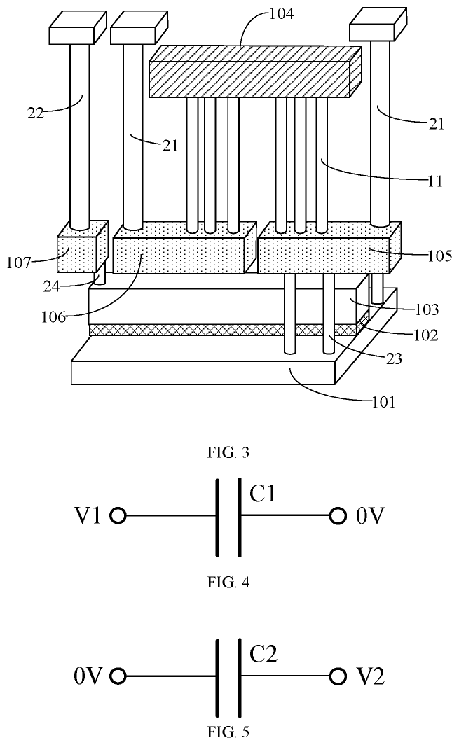

FIG. 1 is a schematic top view of a semiconductor structure according to an embodiment of the present disclosure; FIG. 2 is an enlarged diagram of a cross-sectional structure of 1 in FIG. 1; and FIG. 3 is a schematic diagram of a three-dimensional structure of a semiconductor structure according to an embodiment of the present disclosure.

Referring to FIGS. 1 to 3, the semiconductor structure includes: an active layer 101, where the active layer 101 includes a channel region; a first dielectric layer 102, where the first dielectric layer 102 covers a top surface of the channel region; a gate layer 103 covering a top surface of the first dielectric layer 102, where the active layer 101, the first dielectric layer 102 and the gate layer 103 constitute a first capacitor, and a first capacitor is coupled between a first potential and a second potential; two groups of first conductive layers 10 positioned on a side of the gate layer 103 away from the active layer 101, where the first conductive layers 10 among the at least two groups of first conductive layers 10 are electrically connected to each other; two groups of second conductive layers 11 cladding a side surface and a bottom surface of the first conductive layer 10, where one group of the second conductive layers 11 is electrically connected to a third potential, and the other group of the second conductive layers 11 is electrically connected to a fourth potential; and two groups of second dielectric layers 12 positioned between the first conductive layers 10 and the second conductive layers 11, where the second dielectric layers 12 are configured to isolate the first conductive layers 10 from the second conductive layers 11. The two groups of the first conductive layers 10, the two groups of the second conductive layers 11 and the two groups of the second dielectric layers 12 together constitute a second capacitor, and the first capacitor and the second capacitor are stacked in a direction perpendicular to a top surface of the gate layer 103.

In some embodiments, the semiconductor structure may be Dynamic Random Access Memory (DRAM), Static Random-Access Memory (SRAM) or Synchronous Dynamic Random-Access Memory (SDRAM).

Two groups of second conductive layers 11 are arranged. The two groups of the second conductive layers 11 are electrically connected to different potentials respectively, such that the two groups of the second conductive layers 11 respectively form an upper electrode and a lower electrode of the second capacitor. In addition, each group of the first conductive layers 10, each group of the second conductive layers 11 and each group of the second dielectric layers 12 are configured to constitute a capacitor group, and each group of the capacitor groups is formed by connecting a plurality of columnar capacitors in parallel. In this way, a capacitance value of the second capacitor is increased. In addition, due to a smaller volume of the capacitor having a columnar structure, the capacitance value of the second capacitor is increased without taking up an excessive volume, such that it is advantageous to improving the stability of the supply voltage while a smaller dimension of the semiconductor structure is maintained.

The first capacitor comprises the active layer 101, the first dielectric layer 102 and the gate layer 103, such that the first capacitor is a metal oxide semiconductor (MOS) capacitor, where the first dielectric layer 102 serves as a dielectric layer, the active layer 101 serves as a first electrode, and the gate layer 103 serves as a second electrode. The first capacitor is coupled between the first potential and the second potential, and may be configured to filter noise between the first potential and the second potential. In some embodiments, a material of the gate layer 103 may be metal, for example, may be at least one of tungsten, molybdenum, titanium, cobalt, or ruthenium.

In some embodiments, the first dielectric layer 102 may be a gate dielectric layer, where the gate dielectric layer is configured to isolate the gate layer 103 from the active layer 101 and serves as the dielectric layer of the first capacitor. In some embodiments, a material of the first dielectric layer 102 may be silicon oxide.

The second conductive layer 11 clads a side surface and a bottom surface of the first conductive layer 10, and the second dielectric layer 12 is positioned between the second conductive layer 11 and the first conductive layer 10 for isolating the first conductive layer 10 from the second conductive layer 11. The second conductive layer 11 is positioned on the side surface and the bottom surface of the first conductive layer 10, such that the second conductive layer 11 forms a U-shaped structure, and an outer contour of the second conductive layer 11 and an outer contour of the first conductive layer 10 have a columnar structure. In this way, the second capacitor constituted by the first conductive layer 10, the second conductive layer 11 and the second dielectric layer 12 is a columnar capacitor. The two groups of the second conductive layers 11 are respectively connected to different potentials, such that the two groups of the second conductive layers 11 may be respectively used as the upper electrode and the lower electrode of the second capacitor. The second dielectric layer 12 is positioned between the first conductive layer 10 and the second conductive layer 11, and serves as a dielectric layer of the second capacitor. In addition, among two groups of the first conductive layers 10, the first conductive layers 10 are electrically connected to each other, such that the electrically connected first conductive layers 10 play a role of charge transmission between the two groups of the second conductive layers 11. In this way, the second capacitor is constituted.

In some embodiments, an example is taken where the two groups of the first conductive layers 10 are respectively denoted as a first group and a second group. Each second conductive layer 11 in the first group is connected to the third potential to serve as the upper electrode, and each second conductive layer 11 in the second group is connected to the fourth potential to serve as the lower electrode. The two groups of the second conductive layers 11 are arranged at intervals. To form charge transmission between the upper electrode and the lower electrode, a first group of the first conductive layers 10 are electrically connected to a second group of the first conductive layers 10. In this way, an electrical connection may be formed between the second conductive layers 11 in the first group and the corresponding second conductive layers 11 in the second group by means of two first conductive layers 10 electrically connected, such that charge transmission between the upper electrode and the lower electrode in the second capacitor is implemented.

In some embodiments, in the two groups of the first conductive layers 10, number of the first conductive layers 10 in each group is multiple, such that number of the capacitors connected in parallel in a capacitor group formed in each group is increased, and the capacitance can be increased. In some embodiments, numbers of the first conductive layers 10 in the two groups may be different, and correspondingly, numbers of the second conductive layers 11 and numbers of the second dielectric layers 12 may also be different. In some other embodiments, the numbers of the first conductive layers 10 in each group may also be the same, the second conductive layer 11 and the first conductive layer 10 are correspondingly arranged, and the second dielectric layer 12 and the first conductive layer 10 are correspondingly arranged. Therefore, numbers of the second conductive layers 11 in the each group are equal, and numbers of the second dielectric layers 12 in each group are equal.

As can be learned from the above analysis, when the first conductive layer 10, the second conductive layer 11 covering the side surface and the bottom surface of the first conductive layer 10, and the second dielectric layer 12 positioned between the first conductive layer 10 and the second conductive layer 11 serve as one columnar structure, each columnar structure in the first group is electrically connected to a corresponding columnar structure in the second group by means of the first conductive layer 10, and one columnar structure in the first group and one corresponding columnar structure in the second group are configured to constitute one sub-capacitor. An example is taken where there are three columnar structures in the first group and there are three columnar structures in the second group, three sub-capacitors may be constituted in total. In addition, among the three sub-capacitors, an upper electrode of each sub-capacitor is connected to the third potential, and a lower electrode of each sub-capacitor is connected to the fourth potential. Therefore, the three sub-capacitors are mutually connected in parallel. A total capacitance value obtained after the sub-capacitors are connected in parallel is equal to a sum of capacitance values of the sub-capacitors. In this way, a capacitance value of the second capacitor constituted by the plurality of sub-capacitors is larger. In addition, due to smaller dimension taken up by a columnar structure, the capacitance value may be increased without greatly increasing a volume taken up by the second capacitor, such that the stability of removing noises between the third potential and the fourth potential can be improved.

In some embodiments, a conductive layer 104 is further included. The conductive layer 104 is positioned at a top of the first conductive layer 10, and comes into electrical contact with each first conductive layer 10 in the two groups of the first conductive layers 10. That is, in the two groups of the first conductive layers 10, each first conductive layer 10 may be electrically connected by means of the conductive layer 104. One conductive layer 104 is arranged and is electrically connected to the two groups of the first conductive layers 10 separately, which is advantageous to simplifying processes of fabricating the semiconductor structure compared to forming an electrical connection between two adjacent first conductive layers 10.

In some embodiments, a cross-sectional shape of each of the first conductive layers 10 in the direction perpendicular to the top surface of the gate layer 103 is U-shaped. The conductive layer 104 includes a body portion 13 and a plurality of extension portions 14, where the plurality of extension portions 14 are positioned on a side of the body portion 13 toward each of the first conductive layers 10, the plurality of extension portions 14 are arranged at intervals, and each of the plurality of extension portions 14 electrically come into contact with an inner wall of one of the first conductive layers 10. In some embodiments, the first conductive layer 10 may have an annular structure, such that a cross-sectional shape of the first conductive layer 10 in a direction perpendicular to a top surface of a gate layer 103 is U-shaped, and an annular structure formed by each extension portion 14 in the conductive layer 104 extending into the first conductive layer 10 comes into contact with a side wall of the first conductive layer 10, such that a contact area between the extension portion 14 and the first conductive layer 10 is large, contact resistance between the first conductive layer 10 and the extension portion 14 can be reduced, and an RC delay can be reduced, thereby facilitating increasing a speed of charge transmission between two first conductive layers 10 that are electrically connected, and improving the performance of the second capacitor.

In some embodiments, the semiconductor structure further includes a first metal layer 105 and a second metal layer 106 spaced apart, where the first metal layer 105 and the second metal layer 106 are positioned on the side of the gate layer 103 away from the active layer 101, the first metal layer 105 is connected to the third potential, the second metal layer 106 is connected to the fourth potential, bottoms of one group of the second conductive layers 11 come into contact with the first metal layer 105, and bottoms of the other group of the second conductive layers 11 come into contact with the second metal layer 106. The second conductive layer 11 clads the side surface and the bottom surface of the first conductive layer 10. A bottom of the second conductive layer 11 herein refers to a portion cladding the bottom surface of the first conductive layer 10. Such arrangement is advantageous to forming a stack structure comprising the first capacitor and the second capacitor in a vertical direction.

In some embodiments, a plurality of first contact plugs 21 may also be provided. For example, two first contact plugs 21 may be provided, where one end of one first contact plug 21 is connected to the third potential, and other end of this first contact plug 21 is connected to the first metal layer 105; and one end of the other first contact plug 21 is connected to the fourth potential, and other end of the other first contact plug 21 is connected to the second metal layer 106. In this way, one group of the second conductive layers 11 may be electrically connected to the third potential, and the other group of the second conductive layer 11 may be electrically connected to the fourth potential. A first contact plug 21, a first metal layer 105 and a second metal layer 106 are arranged to separately connect the second conductive layers 11 to the third potential and the fourth potential. In this way, space in the semiconductor structure may be properly used, such that no mutual interference is generated between different electrical connection structures, thereby implementing the normal performance of the semiconductor structure. In some embodiments, the first metal layer 105 and the second metal layer 106 may be arranged in the same layer. In some embodiments, a material of the first metal layer 105 and a material of the second metal layer 106 may be at least one of tungsten, molybdenum, titanium, cobalt, or ruthenium.

In some embodiments, the active layer 101 further includes doped regions positioned on two sides of the channel region, where the doped regions are electrically connected to the first metal layer 105, and the first potential and the third potential are the same potential. In some embodiments, a dopant ion type of the channel region may be different from a dopant ion type of the doped region. For example, the dopant ion type of the channel region may be P-type, and the dopant ion type of the doped region may be N-type; or the dopant ion type of the channel region may be N-type, and the dopant ion type of the doped region may be P-type.

The doped region in the active layer 101 is electrically connected to the first metal layer 105. That is, the doped region serves as a first electrode, and the first electrode is electrically connected to the first potential by means of the first metal layer 105. One of the two groups of the second conductive layers 11 is also electrically connected to the first metal layer 105. That is, one substrate in the second capacitor is electrically connected to the third potential by means of the first metal layer 105. The first potential and the third potential are the same potential. As can be seen, one electrode of the first capacitor and one electrode of the second capacitor share the same first metal layer 105 and are connected to the same potential. In this way, connection wires in the semiconductor structure may be saved, which is advantageous to facilitating rational planning of wiring arrangement and simplifying a layout of the semiconductor structure.

In some embodiments, the semiconductor structure further includes a plurality of third contact plugs 23 positioned between the first metal layer 105 and the doped region, and the first metal layer 105 is electrically connected to the doped region by means of the third contact plugs 23. In this way, a certain height clearance may be formed between the first metal layer 105 and the gate layer 103 to prevent electrical interference caused by the contact between the first metal layer 105 and the gate layer 103.

In some embodiments, the semiconductor structure further includes a third metal layer 107, where the third metal layer 107 is positioned on the side of the gate layer 103 away from the active layer 101, the gate layer 103 is electrically connected to the third metal layer 107, the third metal layer 107 is connected to the second potential, and the second potential is not equal to the fourth potential. That is, one electrode of the first capacitor may be connected to the first potential through the first metal layer 105, and the other electrode of the first capacitor may be connected to the second potential through the third metal layer 107. In some embodiments, the third metal layer 107 may be connected to the second potential through the second contact plug 22. In some embodiments, the semiconductor structure further includes a fourth contact plug 24, where the fourth contact plug 24 is positioned between the third metal layer 107 and the gate layer 103, and the third metal layer 107 is electrically connected to the gate layer 103 through the fourth contact plug 24. In some embodiments, a material of the third metal layer 107 may be the same as a material of the first metal layer 105 and a material of the second metal layer 106.

The second potential is not equal to the fourth potential. That is, in some embodiments, although one electrode of the first capacitor and one electrode of the second capacitor are both connected to the first potential (the third potential), the other electrode of the first capacitor and the other electrode of the second capacitor are respectively connected to different potentials, such that the first capacitor and the second capacitor may be configured to denoise the two different potentials, thereby stabilizing two supply voltages.

In some embodiments, the first potential and the third potential are ground terminals, the second potential is a first supply voltage, and the fourth potential is a second supply voltage. That is, the first capacitor is coupled between the ground terminal and the first supply voltage to denoise the first supply voltage and maintain the stability of the first supply voltage. The second capacitor is coupled between the ground terminal and the second supply voltage to denoise the second supply voltage and maintain the stability of the second supply voltage. That is, the first capacitor and the second capacitor stacked are arranged in the semiconductor structure, and are respectively configured to reduce noise at different power supplies, such that the stability and the compatibility of the semiconductor structure can be improved while a smaller dimension of the semiconductor structure is maintained.

In some embodiments, the first supply voltage may be a positive voltage, for example, may be a positive-voltage power supply at 3.3 V; and the second supply voltage may be a negative voltage, for example, may be a negative-voltage power supply at −0.5 V. The first capacitor is a MOS capacitor, and the first dielectric layer 102 in the first capacitor is thinner, such that a larger capacitance may be provided. Therefore, the first capacitor is coupled between a larger supply voltage and the ground terminal, to provide a stable power supply. In some other embodiments, the first supply voltage may also be a negative voltage, and the second supply voltage may also be a positive voltage. In still other embodiments, both the first supply voltage and the second supply voltage may be positive voltages or negative voltages.

Reference may be made to FIG. 4 for details. A first capacitor C1 is coupled between a first supply voltage V1 and the ground terminal. Referring to FIG. 5, a second capacitor C2 is coupled between a second supply voltage V2 and the ground terminal. The first capacitor and the second capacitor are separately coupled between different potentials, to denoise the two different potentials.

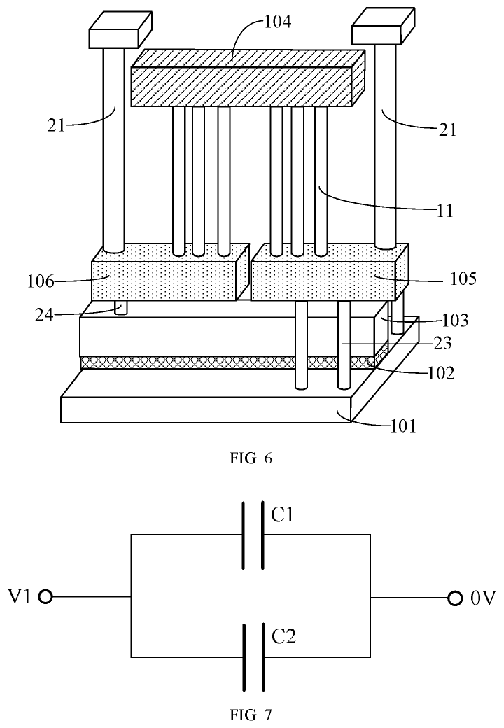

Referring to FIG. 6, in some other embodiments, the gate layer 103 is electrically connected to the second metal layer 106, and the second potential and the fourth potential are the same potential. That is, one group of the second conductive layers 11 and the gate layer 103 share the second metal layer 106 and are connected to the same potential. In this way, in some embodiments, when the doped region is electrically connected to the first metal layer 105, one electrode in the first capacitor and one electrode in the second capacitor are electrically connected to the same potential, and the other electrode in the first capacitor and the other electrode in the second capacitor are electrically connected to the same potential. In this way, a parallel connection relationship is formed between the first capacitor and the second capacitor, such that a total capacitance value is a sum of a capacitance value of the first capacitor and the capacitance value of the second capacitor. In this way, the capacitance value of the decoupling capacitor in the semiconductor structure can be increased, to provide a stable power supply.

In some embodiments, the first potential and the third potential are ground terminals, and the second potential and the fourth potential are first supply voltages. In some embodiments, the first supply voltage may be a positive-voltage power supply, and the first supply voltage may be a positive-voltage power supply with a low voltage, for example, 1.2 V. In some other embodiments, the first supply voltage may also be a negative-voltage power supply. Reference may be made to FIG. 7 for details. In some embodiments, an upper electrode of the first capacitor C1 and an upper electrode of the second capacitor C2 are connected to the first supply voltage V1, and a lower electrode of the first capacitor C1 and a lower electrode of the second capacitor C2 are connected to the ground terminal. That is, the first capacitor C1 and the second capacitor C2 are connected in parallel to the same potential, such that the total capacitance value can be increased, thereby improving a stabilization effect on the supply voltage.

In some embodiments, the two groups of the first conductive layers 10 are denoted as one large group, and the one large group includes a first group of the first conductive layers 10 and a second group of the first conductive layers 10, where a second conductive layer 11 on an outer side of the first group of the first conductive layers 10 is connected to the third potential, and a second conductive layer 11 on an outer side of the second group of the first conductive layers 10 is connected to the fourth potential. There are a plurality of large groups, and among adjacent two of the plurality of large groups, a first group of the second conductive layers 11 in one large group are electrically connected to a second group of the second conductive layers 11 in the other large group. It is to be understood that the two groups of the first conductive layers 10, the two groups of the second conductive layers 11 and the two groups of the second dielectric layers 12 are configured to form one second capacitor. That is, one large group corresponds to one second capacitor. When there are a plurality of large groups, there are a plurality of second capacitors. When a first group of the second conductive layers 11 serves as the upper electrode and a second group of the second conductive layers 11 serves as the lower electrode, the first group of the second conductive layers 11 in one large group is electrically connected to the second group of the second conductive layers 11 in the other large group. That is, the upper electrode of one second capacitor is electrically connected to the lower electrode of the other second capacitor, such that a series connection relationship is formed between the two second capacitors. It is to be understood that the second group of the second conductive layers 11 remained in one large group and the first conductive layers 10 remained in the other large group are electrically connected to the third potential and the fourth potential respectively, such that the two second capacitors connected in series are configured to remove noises between the third potential and the fourth potential.

It is to be understood that, after a plurality of second capacitors are connected in series, the plurality of second capacitors are caused to divide a total supply voltage, such that a voltage withstood by two ends of each of the second capacitors is obtained by dividing a total voltage by number of second capacitors connected in series. As can be seen, the plurality of second capacitors are connected in series, such that the second capacitors connected in series can withstand a higher voltage, and thus the second capacitor may be applied to a larger potential, to improve the compatibility of the second capacitor.

In some embodiments, number of the large groups is 2. It is to be understood that a reciprocal of a total capacitance value of two second capacitors connected in series is equal to a sum of reciprocals of the capacitance values of the two second capacitors. That is, the total capacitance value is decreased after the second capacitors are connected in series. Therefore, the number of the large groups is set only to 2. That is, two second capacitors are formed, and the two second capacitors are connected in series. In this way, in one aspect, after the two second capacitors are connected in series, a voltage withstood at two ends of each second capacitor is reduced to half of the original voltage, such that the second capacitor can withstand a higher voltage. In another aspect, only two second capacitors are connected in series, such that the total capacitance value after the series connection does not drop too much, denoising capability of the second capacitor is well maintained, and thus the second capacitor may be configured to denoise a larger voltage, to provide a stable power supply.

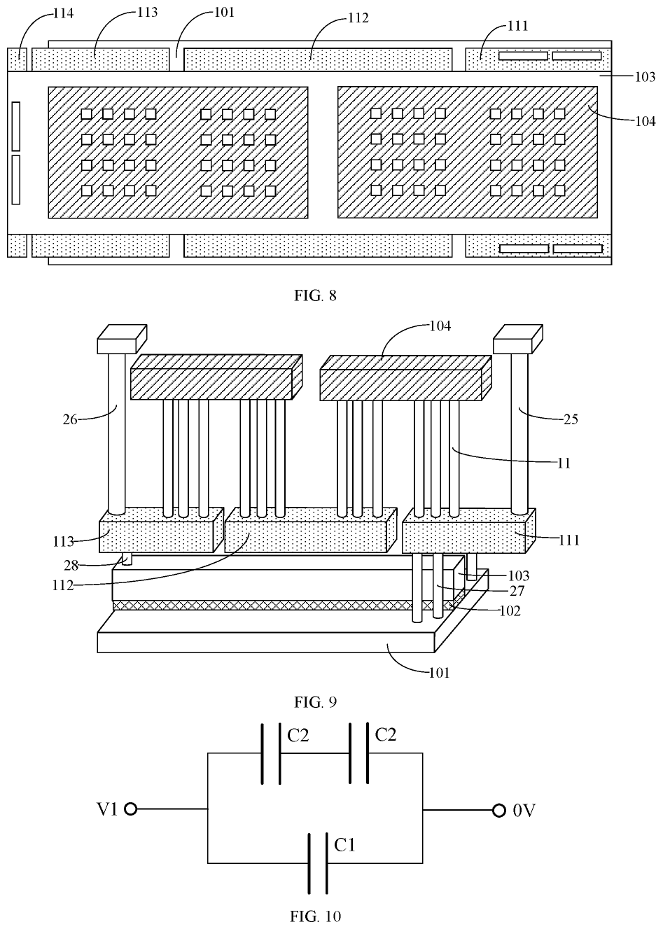

Referring to FIG. 8 and FIG. 9, in some embodiments, the semiconductor structure further includes a fourth metal layer 111, a fifth metal layer 112 and a sixth metal layer 113 arranged at intervals. The fourth metal layer 111 is connected to the third potential, and the sixth metal layer 113 is connected to the fourth potential. Bottoms of the first group of the second conductive layers 11 in one large group come into contact with the fourth metal layer 111, bottoms of the second group of the second conductive layers 11 come into contact with the fifth metal layer 112, bottoms of the first group of the second conductive layers 11 in the other large group come into contact with the fifth metal layer 112, and bottoms of the second group of the second conductive layers 11 come into contact with the sixth metal layer 113. When the first group of the second conductive layers 11 serves as the upper electrode and the second group of the second conductive layers 11 serves as the lower electrode, the lower electrode of the second capacitor corresponding to one large group and the upper electrode of the second capacitor corresponding to the other large group share the same fifth metal layer 112. That is, the upper electrodes and the lower electrodes of the two second capacitors connected in series are electrically connected by means of the fifth metal layer 112. In addition, the other upper electrode of one of the two second capacitors is electrically connected to the third potential, and the other lower electrode of the other one of the two second capacitors is electrically connected to the fourth potential. In this way, the two second capacitors connected in series are coupled between the third potential and the fourth potential.

In some embodiments, the fourth metal layer 111 may be connected to the third potential through the fifth contact plug 25, and the fifth metal layer 112 may be connected to the fourth potential through the sixth contact plug 26. In some embodiments, materials of the fourth metal layer 111, the fifth metal layer 112 and the sixth metal layer 113 may be at least one of tungsten, molybdenum, titanium, cobalt or ruthenium.

In some embodiments, the active layer 101 further includes doped regions positioned on two sides of the channel region, where the doped regions are electrically connected to the fourth metal layer 111, and the first potential and the third potential are the same potential. That is, as the first electrode of the first metal layer 105, the doped region shares the same fourth metal layer 111 with the upper electrode of one second capacitor, and is connected to the same potential. In this way, the connection wires in the semiconductor structure may be saved, which is advantageous to simplifying a layout of the semiconductor structure. In some embodiments, the first potential and the third potential are ground terminals. That is, the first capacitor is coupled between the ground terminal and the second potential, and the second capacitor is coupled between the ground terminal and the fourth potential, such that the first capacitor may be configured to stabilize the second potential, and the second capacitor may be configured to stabilize the fourth potential.

In some embodiments, the fourth metal layer 111 may be electrically connected to the active layer 101 in the doped region by means of a seventh contact plug 27, where the seventh contact plug 27 is perpendicular to the surface of the substrate. By providing the seventh contact plug 27, a larger height clearance may be formed between the fourth metal layer 111 and the gate layer 103, to prevent mutual interference caused by the electrical contact between the fourth metal layer 111 and the gate layer 103. In some embodiments, the fourth metal layer 111, the fifth metal layer 112 and the sixth metal layer 113 may be arranged in the same layer.

In some embodiments, the gate layer 103 is electrically connected to the sixth metal layer 113, and the second potential and the fourth potential are the same potential. As the lower electrode of the first capacitor, the gate layer 103 shares the same sixth metal layer 113 with the second group of the second conductive layers 11 in the other large group. That is, the lower electrode of the second capacitor not connected to the ground terminal and the lower electrode of the first capacitor are electrically connected to the same potential. Reference may be made to FIG. 10 for details. The upper electrode of one second capacitor C2 and the upper electrode of the first capacitor C1 are together connected to the first supply voltage V1, and the lower electrode of the other second capacitor C2 and the lower electrode of the first capacitor C1 are together connected to the ground terminal, such that after being connected in series, the two second capacitors C2 are then connected to the first capacitor C1 in parallel. That is, the total capacitance value is equal to a sum of a capacitance value obtained after the two second capacitors C2 are connected in series and a capacitance value of the first capacitor C 1. However, in the first capacitor C1, the first dielectric layer 102 is thinner, such that the first capacitor C1 can provide a larger capacitance. Therefore, after the first dielectric layer 102 is connected to the first capacitor C1 in series, the total capacitance value may be larger. In this way, in one aspect, two ends of the second capacitor C2 may withstand a higher voltage; and in another aspect, the total capacitance value may be larger, such that a better denoising effect may be provided for a larger supply voltage, to provide a stable voltage.

In some embodiments, the second potential and the fourth potential may be the same supply voltage, for example, may be a positive-voltage power supply. In some embodiments, a voltage value of the positive-voltage power supply may be 2.2 V, 3.3 V, or greater than 3.3 V.

In some embodiments, the sixth metal layer 113 may be electrically connected to the gate layer 103 of the doped region through an eighth contact plug 28, where the eighth contact plug 28 is perpendicular to the surface of the substrate. In some embodiments, materials of the first contact plug to the eighth contact plug may be the same, for example, metal, or at least one of tungsten, molybdenum, titanium, cobalt or ruthenium, or polysilicon.

In some other embodiments, the semiconductor structure further includes: a seventh metal layer (not shown), where the seventh metal layer is positioned on the side of the gate layer 103 away from the active layer 101, the gate layer 103 is electrically connected to the seventh metal layer, and the seventh metal layer is connected to the second potential, and the second potential is not equal to the fourth potential. That is, as the lower electrode of the first capacitor, the gate layer 103 and the lower electrode of the second capacitor not connected to the ground terminal may be respectively connected to two different potentials, such that the gate layer 103 may be configured to stabilize two different supply voltages. In some embodiments, the second potential may be a first supply voltage and the fourth potential may be a second supply voltage. In some embodiments, the first supply voltage may be a positive-voltage power supply, and the second supply voltage may be a negative-voltage power supply.

In the semiconductor structure provided by the foregoing embodiment, the two groups of the second conductive layers 11 are arranged. The two groups of the second conductive layers 11 are electrically connected to different potentials, respectively, such that the two groups of the second conductive layers 11 respectively form the upper electrode and the lower electrode of the second capacitor. In addition, a plurality of columnar second conductive layers 11 are configured to constitute a capacitor group, such that the second capacitor is formed by a plurality of capacitor groups connected in parallel, thereby increasing the capacitance value of the second capacitor. In addition, due to a smaller volume of the capacitor having a columnar structure, the capacitance value of the second capacitor is increased without taking up an excessive volume, such that it is advantageous to improving the stability of the supply voltage while a smaller dimension of the semiconductor structure is maintained.

Those of ordinary skill in the art can understand that the above-mentioned embodiments are some embodiments for realizing the present disclosure, but in practical applications, various changes may be made to them in form and details without departing from the spirit and scope of the present disclosure. Any person skilled in the art can make their own changes and modifications without departing from the spirit and scope of the present disclosure. Therefore, the protection scope of the present disclosure shall be subject to the scope defined by the claims.

What is claimed is:

1. A semiconductor structure, comprising:
an active layer, wherein the active layer comprises a channel region;
a first dielectric layer, wherein the first dielectric layer covers a top surface of the channel region;
a gate layer covering a top surface of the first dielectric layer, the active layer, the first dielectric layer and the gate layer constituting a first capacitor, wherein the first capacitor is coupled between a first potential and a second potential;
two groups of first conductive layers positioned on a side of the gate layer away from the active layer, wherein the first conductive layers among the two groups of first conductive layers are electrically connected to each other;
two groups of second conductive layers, wherein each of the second conductive layers clads a side surface and a bottom surface of the first conductive layer, one group of the second conductive layers is electrically connected to a third potential, and the other group of the second conductive layers is electrically connected to a fourth potential; and
two groups of second dielectric layers, wherein each of the second dielectric layers is positioned between each of the first conductive layers and each of the second conductive layers, the second dielectric layers being configured to isolate the first conductive layers from the second conductive layers, the two groups of the first conductive layers, the two groups of the second conductive layers and the two groups of the second dielectric layers together constituting a second capacitor, and the first capacitor and the second capacitor being stacked in a direction perpendicular to a top surface of the gate layer.

2. The semiconductor structure according to claim 1, wherein there are a plurality of first conductive layers in either of the two groups of the first conductive layers.

3. The semiconductor structure according to claim 1, further comprising: a third conductive layer, wherein the third conductive layer is positioned at a top of each of the first conductive layers, and comes into electrical contact with each of the first conductive layers in the two groups of the first conductive layers.

4. The semiconductor structure according to claim 3, wherein a cross-sectional shape of each of the first conductive layers in the direction perpendicular to the top surface of the gate layer is U-shaped, and the first conductive layer comprises: a body portion and a plurality of extension portions, the plurality of extension portions being positioned on a side of the body portion toward each of the first conductive layers, the plurality of extension portions being arranged at intervals, and each of the plurality of extension portions electrically coming into contact with an inner wall of one of the first conductive layers.

5. The semiconductor structure according to claim 1, further comprising: a first metal layer and a second metal layer spaced apart, wherein the first metal layer and the second metal layer are positioned on the side of the gate layer away from the active layer, the first metal layer being connected to the third potential, the second metal layer being connected to the fourth potential, bottoms of one group of the second conductive layers coming into contact with the first metal layer, and bottoms of the other group of the second conductive layers coming into contact with the second metal layer.

6. The semiconductor structure according to claim 5, wherein the active layer further comprises: doped regions positioned on two sides of the channel region, the doped regions being electrically connected to the first metal layer, and the first potential and the third potential being the same potential.

7. The semiconductor structure according to claim 6, further comprising: a third metal layer, wherein the third metal layer is positioned on the side of the gate layer away from the active layer, the gate layer being electrically connected to the third metal layer, the third metal layer being connected to the second potential, and the second potential being not equal to the fourth potential.

8. The semiconductor structure according to claim 7, wherein the first potential and the third potential are ground terminals, the second potential being a first supply voltage, and the fourth potential being a second supply voltage.

9. The semiconductor structure according to claim 6, wherein the gate layer is electrically connected to the second metal layer, the second potential and the fourth potential being the same potential.

10. The semiconductor structure according to claim 9, wherein the first potential and the third potential are ground terminals, and the second potential and the fourth potential are first supply voltages.

11. The semiconductor structure according to claim 1, wherein the two groups of the first conductive layers are denoted as one large group, the one large group comprising: a first group of the first conductive layers and a second group of the first conductive layers, a second conductive layer on an outer side of the first group of the first conductive layers being connected to the third potential, and a second conductive layer on an outer side of the second group of the first conductive layers being connected to the fourth potential; there are a plurality of large groups, and among adjacent two of the plurality of large groups, a first group of the second conductive layers in one large group being electrically connected to a second group of the second conductive layers in the other large group.

12. The semiconductor structure according to claim 11, wherein number of the large groups is two.

13. The semiconductor structure according to claim 12, further comprising: a fourth metal layer, a fifth metal layer and a sixth metal layer arranged at intervals, wherein
the fourth metal layer is connected to the third potential; and
the sixth metal layer is connected to the fourth potential, bottoms of the first group of the second conductive layers in one large group coming into contact with the fourth metal layer, bottoms of the second group of the second conductive layers coming into contact with the fifth metal layer, bottoms of the first group of the second conductive layers in the other large group coming into contact with the fifth metal layer, and bottoms of the second group of the second conductive layers coming into contact with the sixth metal layer.

14. The semiconductor structure according to claim 13, wherein the active layer further comprises: doped regions positioned on two sides of the channel region, the doped regions being electrically connected to the fourth metal layer, and the first potential and the third potential being the same potential.

15. The semiconductor structure according to claim 14, wherein the gate layer is electrically connected to the sixth metal layer, the second potential and the fourth potential being the same potential.

16. The semiconductor structure according to claim 14, further comprising: a seventh metal layer, wherein the seventh metal layer is positioned on the side of the gate layer away from the active layer, the gate layer being electrically connected to the seventh metal layer, the seventh metal layer being connected to the second potential, and the second potential being not equal to the fourth potential.
